(19) United States
(12) Patent Application Publication
(10) Pub. No.: US 2007/0215992 A1
(43) Pub. Date: Sep. 20, 2007

(54) Chip package and wafer treating method for making adhesive chips

(76) Inventors: Geng-Shin Shen, Tainan County (TW); Chun-Hung Lin, Tainan County (TW)

Correspondence Address: J.C. Patents, Inc., Suite 250, 4 Venture, Irvine, CA, 92618, US

(21) Appl. No.: 11/481,719

(22) Filed: Jul. 5, 2006

(30) Foreign Application Priority Data
Mar. 17, 2006 (TW) 95109125

(51) Int. Cl. H01L 23/495

(52) U.S. Cl. 257/668

(57) ABSTRACT

A wafer treating method for making adhesive chips is provided. A liquid adhesive with two-stage property is coated on a surface of a wafer. Then, the wafer is pre-cured to make the liquid adhesive transform an adhesive film having B-stage property which has a glass transition temperature between −40 and 175 degree C. for example. After positioning the wafer, the wafer is singulated to form a plurality of chips with adhesive for chip-to-chip stacking, chip-to-substrate or chip-to-lead frame attaching.

### CROSS-REFERENCE TO RELATED APPLICATION

This application claims the priority benefit of Taiwan application serial no. 95109125, filed on Mar. 17, 2006. All disclosure of the Taiwan application is incorporated herein by reference.

### BACKGROUND OF THE INVENTION

1. Field of the Invention

The present invention is generally relating to a wafer treating technique after finishing integrated circuits on a wafer, particularly to a chip package and a wafer treating method for making adhesive chips.

2. Description of Related Art

After manufacturing the integrated circuits on a semiconductor wafer, a plurality of chips are singulated from the semiconductor wafer and according to various packaging styles are attached on a proper IC substrate, or one of chips is attached one on top of the other chip to form multi-chip stack. Chip is attached onto a printed circuit board to form Ball Grid Array (BGA) package. Chip is attached to chip pad or inner leads of a lead frame to form Thin Small Outline Package (TSOP). Conventional adhesive for chip-attaching is thermosetting silver liquid compound or solid polyimide adhesive tape, which is applied on a carrier (e.g., substrate, lead frame or lower chip) during chip-attaching.

A method for assembling multi-chip module disclosed from U.S. Pat. No. 2001/0005935 is to attach a larger chip onto a substrate using a chip attach machine, then a smaller chip is affixed on the larger chip without using a chip attach machine. The adhesive attaching the larger chip and the smaller chip conventionally is a liquid thermosetting adhesive or solid polyimide tape. However, that is failed to disclose the procedure of coating the adhesive (firstly coated on the smaller chip or on the larger chip prior to chip-attaching and the procedure of wire-bonding. On one hand, when a liquid thermosetting adhesive is used for chip-attaching prior wire-bonding, it is difficult to pre-coat on the smaller chip (upper chip) and also easy to contaminate the bonding pads of the larger chip (lower chip) due to flowage of liquid thermosetting adhesive. On the other hand, when the liquid adhesive is printed after wire-bonding, the printing screen is unable to be placed on the larger chip (or substrate) with bonding wires, so that adhesive must be applied on the larger chip before wire-bonding. Thus, the limits for multi-chip packaging process are quite a lots, lead to package uneasily. Alternatively, a solid adhesive tape may also be used for chip-attaching, but cost of adhesive tape is high and the adhesive tape is demanded double-sided adhesive for chip-to-chip, chip-to-substrate or chip-to-lead frame bonding. Conventionally the adhesive tape is firstly attached on a substrate (lead frame or larger chip) in predetermined pattern, then a chip is bonded on the adhesive tape. The chips do not have adhesive after singulating from a wafer.

### SUMMARY OF THE INVENTION

Accordingly, the present invention is directed to a wafer treating method for making adhesive chips. The wafer treating method for making adhesive chips is performed by utilizing a liquid adhesive with two-stage property printed on a wafer. The printed adhesive with two-stage property is pre-cured to become solid without flowable and adhesive under room temperature (B-stage condition), then after singulating the wafer, a plurality of chips with B-stage adhesive will be obtained for decreasing cost of forming adhesive.

The present invention is directed to a chip package, which utilized an adhesive layer between the carrier and the chip, so the chip-to-substrate, or chip-to-lead frame package structure will be made easily.

The present invention is directed to a chip package, which utilized an adhesive layer between two chips, so the chip-to-chip package structure will be made easily.

In accordance with the wafer treating method for making adhesive chips of the present invention, a semiconductor wafer having integrated circuits is provided. The wafer has a plane surface, such as an active surface or an inactive surface. A liquid adhesive with two-stage property is evenly coated on the partial or overall surface of the wafer. Next, the wafer is pre-cured by heating or ultraviolet rays to make the adhesive with two-stage property become an adhesive film with B-stage property. Then a positioning tape is provided to contact with the adhesive film for positioning the wafer. Afterwards, the wafer is singulated via the positioning tape so as to form a plurality of chips with the adhesive film.

In accordance with an embodiment of the present invention, a chip package is provided. The chip package comprises a carrier, a first chip, a first adhesive layer and a molding compound. The first chip is disposed on the carrier and electrically connected with the carrier. The first adhesive layer is disposed between the carrier and the first chip, wherein an area of the first adhesive layer is not larger than an area of the first chip. The molding compound is disposed on the carrier to cover the first chip.

According to an embodiment of the present invention, the chip package further comprises a plurality of first bonding wires, electrically connected with the carrier and the first chip.

According to an embodiment of the present invention, the carrier is a package substrate or a lead frame, wherein the package substrate has a slit exposing a portion of the first chip. Additionally, the first adhesive layer can be an adhesive film having B-stage property or an adhesive film, for example.

According to an embodiment of the present invention, the chip package further comprises a second adhesive layer and a second chip, wherein the second adhesive layer is disposed on the first chip. The second chip is disposed on the second adhesive layer, wherein an area of the second adhesive layer is not larger than an area of the second chip, and the second chip is electrically connected with the carrier.

According to an embodiment of the present invention, the chip package further comprises a plurality of second bonding wires, electrically connected with the carrier and the second chip. A portion of the first bonding wires are covered with the second adhesive layer, for example, wherein the second bonding wires and the second chip can be covered with the molding compound.

According to an embodiment of the present invention, wherein the second adhesive layer is disposed between an inactive surface of the second chip and an inactive surface of the first chip or between an inactive surface of the second chip and an active surface of the first chip or between an active surface of the second chip and an active surface of the first chip.

According to an embodiment of the present invention, wherein the second adhesive layer is an adhesive film having B-stage property or an adhesive film.

In accordance with an embodiment of the present invention, a chip package is provided. The chip package comprises a carrier, a first chip, a second chip, a second adhesive layer, and a molding compound. The first chip is disposed on the carrier and electrically connected with the carrier. The second chip is disposed on the first chip and electrically connected with the carrier. The second adhesive layer is disposed between the first chip and the second chip, wherein an area of the second adhesive layer is not larger than an area of the second chip. The molding compound is disposed on the carrier to cover the first chip, the second chip, and the second adhesive layer.

According to an embodiment of the present invention, the chip package further comprises a plurality of first bonding wires, electrically connected with the carrier and the first chip. And a portion of the first bonding wires are covered with the second adhesive layer, for example.

According to an embodiment of the present invention, the chip package further comprises a plurality of second bonding wires, electrically connected with the carrier and the second chip.

According to an embodiment of the present invention, the second adhesive layer is an adhesive film having B-stage property or an adhesive film.

According to an embodiment of the present invention, the chip package further comprises a first adhesive layer, disposed between the carrier and the first chip.

According to an embodiment of the present invention, the first adhesive layer is an adhesive film having B-stage property or an adhesive film.

According to an embodiment of the present invention, the carrier is a package substrate or a lead frame, wherein the carrier has a slit exposing a portion of the first chip.

According to an embodiment of the present invention, wherein the second adhesive layer is disposed between an inactive surface of the second chip and an inactive surface of the first chip or between an inactive surface of the second chip and an active surface of the first chip or between an active surface of the second chip and an active surface of the first chip.

According to an embodiment of the present invention, wherein the first chip is electrically connected with the carrier via a plurality of solder bumps.

To sum up, the present invention utilizes an adhesive layer such as an adhesive film having B-stage property or an adhesive film to dispose it on a chip or a carrier, and the adhesive film having B-stage property or the film will not impair the bonding wires or bonding pads of existed chip-to-substrate, or chip-to-lead frame package structure even when an inactive surface of the chip is fully covered with the adhesive film having B-stage property or the film in the step of chip-to-chip stacked. Therefore, the chip-to-chip stack, chip-to-substrate, or chip-to-lead frame package structure can be easily or efficiently fabricated by the adhesive layer without taking account into the existed bonding wires or bonding pads.

Additionally, by utilizing the adhesive layer, the chip can be provided to affix to a substrate, another chip, a printed circuit board, a ceramic circuit board or a lead frame without extra adhesive, so the adhesive layer can be efficiently, broadly used in chip-to-chip stack or chip-to-substrate attach for various packages at low cost.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart of a wafer treating method for making adhesive chips in accordance with the present invention.

FIG. 2 is a front view of a provided wafer in accordance with a wafer treating method for making adhesive chips of the present invention.

FIG. 3A to FIG. 3D are cross-sectional views of a wafer in wafer treating process in accordance with a first embodiment of the present invention.

FIG. 3E to FIG. 3G are cross-sectional views of an adhesive chip made from the first embodiment in chip-to-chip stack.

FIG. 3H is a cross-sectional view of a chip-to-chip package according to the first embodiment of the present invention if applied in a ball grid array package.

FIG. 4A to FIG. 4D are cross-sectional views of a wafer in wafer treating process in accordance with a second embodiment of the present invention.

FIG. 4E to FIG. 4F are cross-sectional views of an adhesive chip made from the second embodiment in chip-to-substrate package.

FIG. 5 is a cross-sectional view illustrating the inactive surface of wafer attached to a position tape for singulation to make adhesive chips in accordance with a third embodiment of the present invention.

FIG. 6 and FIG. 7 are cross-sectional views illustrating an adhesive chip made from the third embodiment in chip-to-lead frame package.

FIG. 8A to FIG. 8D are cross-sectional views of a wafer in wafer treating process in accordance with a fourth embodiment of the present invention.

FIG. 8E to FIG. 8F are cross-sectional views of an adhesive chip made from the fourth embodiment in chip-to-substrate package.

FIG. 8G is a cross-sectional view of a chip-to-substrate package structure according to the fourth embodiment in the present invention if applied in a ball grid array package.

FIG. 9A to FIG. 9C are cross-sectional views of an adhesive chip made from the fourth embodiment in chip-to-chip package.

FIG. 9D is a cross-sectional view of a chip-to-chip package according to the fourth embodiment in the present invention if applied in a ball grid array package.

FIG. 10A to FIG. 10B are cross-sectional views of an adhesive chip made from the fourth embodiment in one chip-to-lead frame package.

FIG. 11A to FIG. 11B are cross-sectional views of an adhesive chip made from the fourth embodiment in two stacked chips-to-lead frame package.

FIG. 12A is a cross-sectional view of an adhesive chip made from the fifth embodiment in chip-to-chip package.

FIG. 12B is a cross-sectional view of a chip-to-chip package according to the fifth embodiment in the present invention if applied in a ball grid array package.

FIG. 12C is a cross-sectional views of an adhesive chip made from the fifth embodiment in two stacked chips-to-lead frame package.

FIG. 13 is a cross-sectional view of FIG. 12A when the first chip is electrically connected with the carrier via a plurality of solder bumps.

FIG. 14A to FIG. 14C are cross-sectional views of an adhesive chip made from a sixth embodiment in chip-to-chip package.

FIG. 15 is another embodiment for disposing solder bumps 30 shown in FIG. 14A.

### DESCRIPTION OF THE EMBODIMENTS

Various specific embodiments of the present invention are disclosed below, illustrating examples of various possible implementations of the concepts of the present invention. The following description is made for the purpose of illustrating the general principles of the invention and should not be taken in a limiting sense. The scope of the invention is best determined by reference to the appended claims.

Referring to the drawings attached, the present invention will be described by means of the embodiments below.

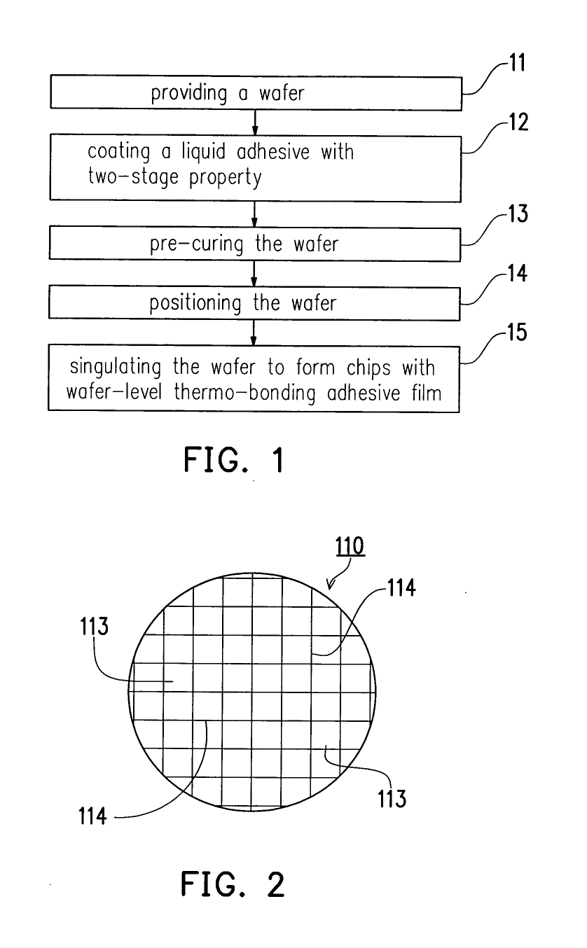

As shown in FIG. 1, the wafer treating method for making adhesive chips according to the present invention comprises the main steps of “providing a wafer” 11, “coating a liquid adhesive with two-stage property” 12, “pre-curing the wafer” 13, “positioning the wafer” 14 and “singulating the wafer to form chips with adhesive film” 15.

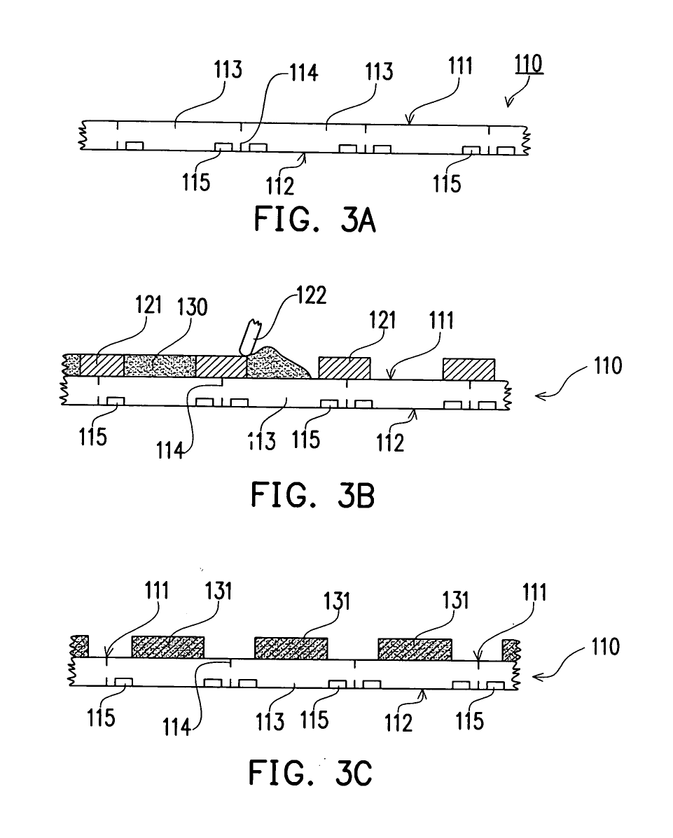

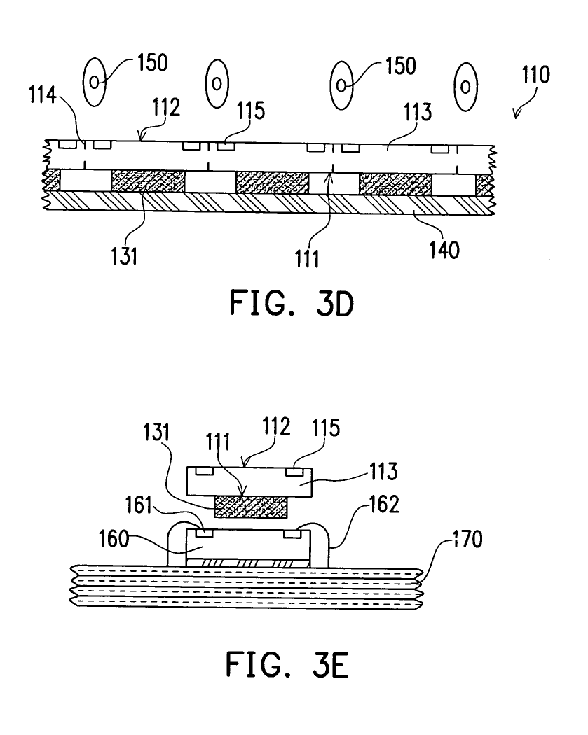

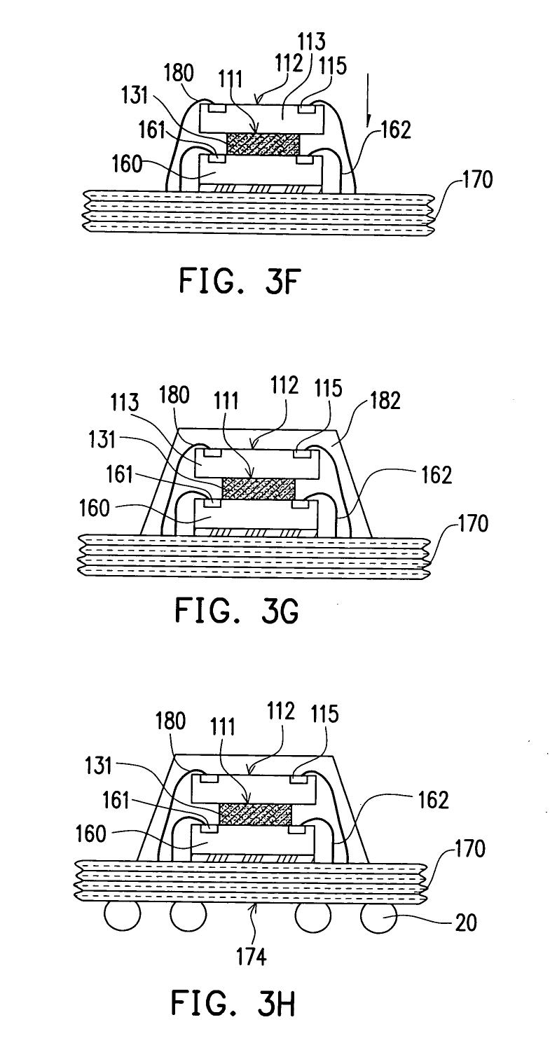

As illustrated in FIG. 2 and FIG. 3A, initially in the step of “providing a wafer” 11, a wafer 110 is provided. The wafer 110 has an active surface 112 which had formed integrated circuits and bonding pads 115, an inactive surface 111 corresponding to the active surface 112 in order to integrate a plurality of chips 113 together. The bonding pads 115 are located on each chip 113. There are straight cutting paths 114 located at the perimeters of the chips 113 to define the chips 113. According to predetermined package or stack process, a surface of the wafer 110 for required to being adhesive is active surface 112 or inactive surface 111. In the first embodiment, the inactive surface 111 of the wafer 110 is predetermined to be adhesive, the inactive surface 111 should face upward. Next, the step of “coating a liquid adhesive with two-stage property” 12 is executed, as shown in FIG. 3B. A liquid adhesive 130 having at least two-stage property (A-stage, B-stage, C-stage) is coated on partially or totally inactive surface 111 of the wafer 110 by screen printing, stencil printing or spin coating. Preferably, a screen 121 is placed on the inactive surface 111 of the wafer 110, then the liquid adhesive 130 with proper flowability is printed on the inactive surface 111 by a scraper 122. In this embodiment, the screen 121 covers the cutting paths 114 of the wafer 110 so that the adhesive 130 with two-stage property is partially printed on the inactive surface 111 of the wafer 110 without covering the cutting paths 114. Since the chips 113 formed in this embodiment are used for chip-to-chip stack, the printed thickness of the adhesive 130 with two-stage property is about 3 to 6 mil and depends on the screen 121. The adhesive 130 with two-stage property includes thermosetting resin or polymer such as polyimide, polyquinolin or benzocyclobutene and that enable dissolution of mentioned-above thermosetting resin such as mix-solvent of butyrolactone and cyclopentanone or 1,3,5-mesitylene, etc. Wherein, the solvent is dispensable in the adhesive 130 with two-stage property. Since the liquid adhesive 130 with two-stage property has A-stage property while coated, the liquid adhesive 130 is fluid enough to be printed.

Next, the step of “pre-curing the wafer” 13 is executed as shown in FIG. 3C, wherein the step of pre-curing can be performed by heating or ultraviolet rays. If the step is performed by heating, the wafer 110 can be placed in an oven to be heated at a proper temperature (about 90 to 150 degree C. approximately) for 1 hour. After the pre-curing procedure, the printed liquid adhesive 130 transforms an adhesive film 131. Otherwise, the pre-curing step 13 is executed by vacuum drying. The adhesive film 131 is solid and has a thickness between about 3 and 8 mil for chip-to-chip stacking, preferably between about 5 and 6 mil. And the adhesive film 131 becomes adhesive when operating temperature is more than its glass transition temperature (Tg), that is to say, the adhesive film 131 possesses B-stage condition and also has thermosetting property. Wherein, the glass transition temperature (Tg) can be between −40 and 175 degree C., for example.

Next, the step of “positioning the wafer” 14 is executed as shown in FIG. 3D, the wafer 110 is turned over to make the inactive surface 111 facing downward and attached to a positioning tape 140. The positioned tape 140 is a wafer positioning tape such as polyvinyl chloride, which has adhesive and is attached to a metal frame with circular opening for wafer-dicing procedure. In the first embodiment, the adhesive film 131 attaches on the positioning tape 140 by the adhesive of the positioning tape 140. After completing the step of “positioning the wafer” 14, the step of “singulating the wafer to form chips with adhesive film” 15 is executed that is along the cutting paths 114 to dice the wafer 110 by using the dicer 150 (laser or diamond cutting tool) of wafer-dicing machine to form a plurality of chips 113 with adhesive film 131. Thus, the adhesive chips 113 not only can be rapidly provided at low cost but also can be used in chip-to-chip stacks or other various packages.

As shown in FIG. 3E, initially another chip 160 is affixed to a carrier such as a substrate 170 and the bonding pads 161 of the chip 160 is electrically connected with the substrate 170 by bonding wires 162, for example, wherein the substrate 170 can be a tape substrate or a ceramic substrate. Then the chip 113 with the adhesive film 131 is sucked by a chip attach machine and is affixed onto the chip 160. A chip-to-chip stack structure will be completed in few seconds, even in less than a second when a thermal compression temperature 120 degree C.˜175 degree C. approximately is supplied at the chip 113 to allow the adhesive film 131 become adhesive (as shown in FIG. 3F). However, it is desirable that the thermal compression temperature and time do not make the adhesive film 131 finish the thermosetting reaction after chip-to-chip attaching.

Thereafter, for example, the bonding wires 180 are wire-bonded to electrically connect the bonding pads 115 of the chip 113 with the substrate 170. However, the wafer treating method for making adhesive chips of the present invention is applicable not only for chip-to-chip stacking but also for chip-to-substrate and chip-to-lead frame attaching for various packages. Alternatively, in the step of “coating the liquid adhesive with two-stage property” 12, a layer of liquid adhesive 130 with two-stage property is completely coated on a portion of the inactive surface 111 of a wafer 110 by spin coating or printing method, then passing through pre-curing step 13, positioning step 14 and singulating step 15, a plurality of chips 113 with adhesive film 131 on the inactive surface thereof are formed for chip-to-substrate attaching. The adhesive film 131 has higher viscous and handling-easier than conventional silver liquid paste so that the contact pads of substrate can be closer to the adhesive chip 113 for making chip scale package (CSP).

Referring to FIG. 3G, thereafter, a molding compound 182 is formed on the substrate 170 to cover the chips 113 and 160 and the bonding wires 162 and 180 to protect them from hurt by external objects such as dust or moisture, so as to complete the manufacturing process of a chip-to-chip package. In another embodiment, in the chip-to-chip package, the adhesive film 131 can be an adhesive layer such as an adhesive film. Additionally, an area of the adhesive film 131 is not larger than an area of the chip 113 (FIG. 3G shows that the area of the adhesive film 131 is smaller than the area of the chip 113).

FIG. 3H is a cross-sectional view of a chip-to-substrate package structure according to the first embodiment in the present invention if applied in a ball grid array package. Referring to FIG. 3H, a plurality of solder balls 20 are disposed on a surface 174 of the substrate 170, so as to accomplish the manufacturing of the ball grid array (BGA) type-chip package. Wherein the ball grid array (BGA) type-chip package is electrically connected with such as a printed circuit board (PCB) (not shown) via these solder balls 20.

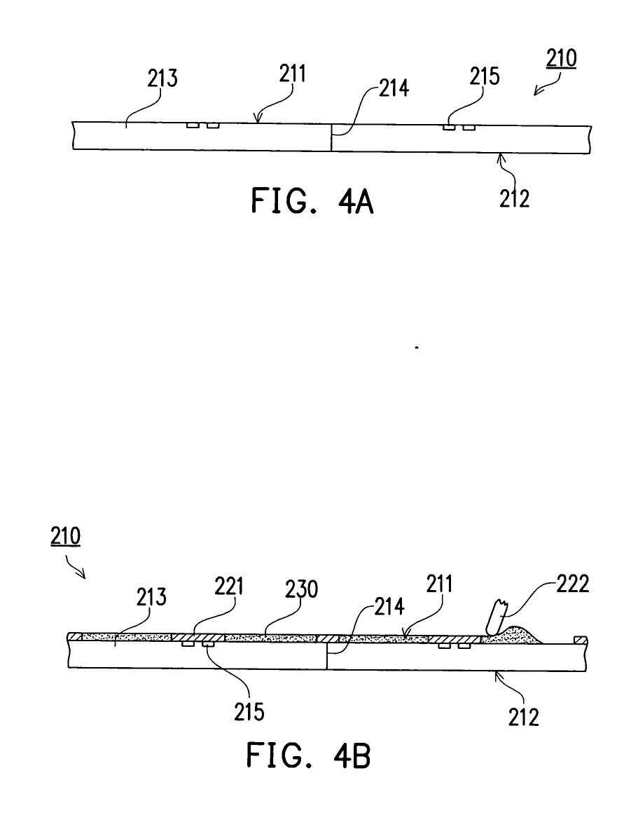

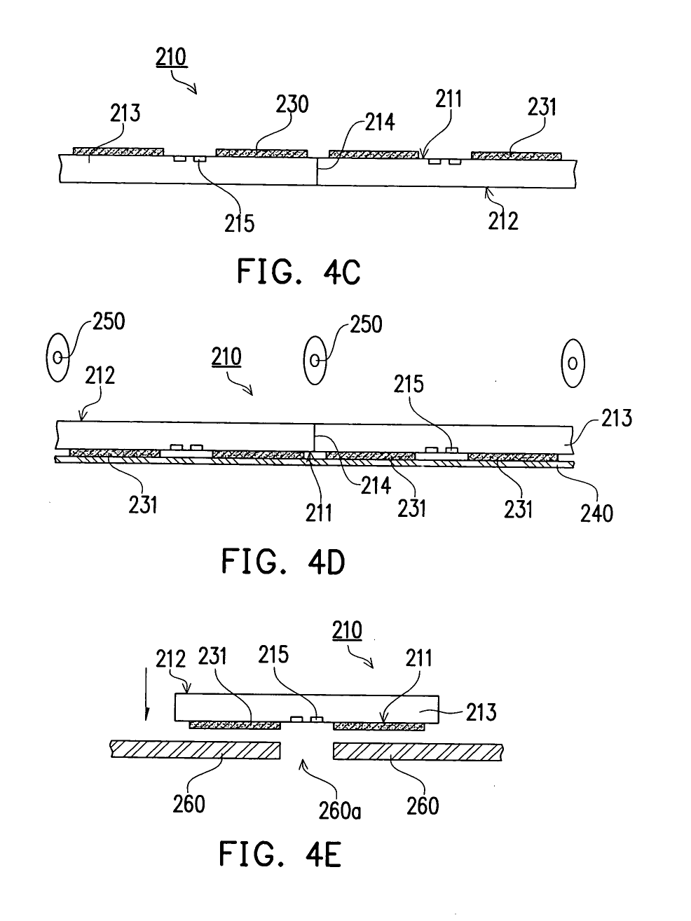

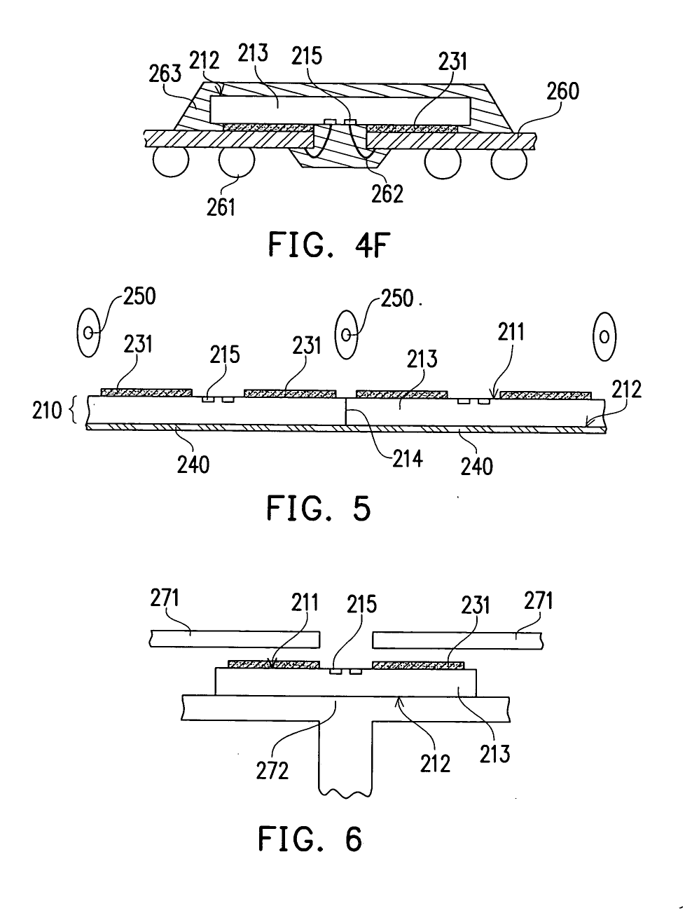

In order to understand the present invention is not limited to the printing surface of wafer, the second embodiment is presented. As shown in FIG. 4A, initially a wafer 210 is provided. The wafer 210 has an active surface 211 having a plurality of bonding pads 215 (or bumps) and an inactive surface 212 corresponding to the active surface 211 to integrate a plurality of chips 213. The bonding pads 215 are located at the center of each chip 213, for example, and the active surface 211 faces upward. Thereafter, as shown in FIG. 4B, a liquid adhesive 230 with two-stage property is formed on the active surface 211 by such as screen printing or stencil printing method. A screen 221 is put on the active surface 211 of the wafer 210, then the liquid adhesive 230 with two-stage property is printed on the active surface 211 by a scraper 222. In the second embodiment, since the screen 221 covers the bonding pads 215 of the wafer 210, the liquid adhesive 230 with two-stage property is partially printed on the active surface 211 of the wafer 210 with predetermined pattern, the thickness thereof is about 1 to 3 mil.

Then, as shown in FIG. 4C, the wafer 210 is pre-cured by heating or ultraviolet rays, for example, so the liquid adhesive 230 with two-stage property on the active surface 211 of the wafer 210 is transformed into an adhesive film 231. The adhesive film 231 has B-stage property and has a glass transition temperature (Tg) between −40 and 175 degree C., for example. That is, the glass transition temperature (Tg) can be more than 40 degree C., so that the adhesive film 231 does not possess adhesive under the normal room temperature for being portable, movable and storable and also possesses thermo-bonding adhesive.

Next, as shown in FIG. 4D, the wafer 210 is turned over so that the active surface 211 faces downward and is positioned onto a positioning tape 240. After the wafer 210 is positioned, it is diced along the cutting paths 214 by a dicer 250 to form a plurality of chips 213 with adhesive film 231 on the active surface 211. Thus, the adhesive chips 213 not only can be rapidly provided at low cost but also can be utilized in various packages. For example, as shown in FIG. 4E, the chip 213 with adhesive film 231 is sucked by a chip attach machine and is affixed to a carrier like a package substrate 260 such as a printed circuit board, a tape substrate or ceramic circuit substrate, wherein the package substrate 260 has a slit 260a.

The chip 213 can be quickly attached to a substrate 260 at the thermal bonding temperature around 120 degree C. to about 175 degree C., for example even in few seconds. The adhesive strength between substrate 260 and chip 213 is provided by means of the adhesive film 231 at the thermal bonding temperature. After the chip 213 is affixed to the substrate 260, the slit 260a thereof will expose a portion of the chip 213, so the bonding wires 262, for example, can be electrically connected with the package substrate 260 and the chip 213 via the slit 260a. Then, the molding compound 263 is disposed on the substrate 260 to cover the bonding wires 262 and the chip 213, in order to protect the bonding wires 262 and the chip 213 from damaged by outside moisture or forces. Also, a BGA package can be fabricated after executing the steps of forming the solder balls 261 on a surface of the substrate 260 far away from the chip 213. (as shown in FIG. 4F).

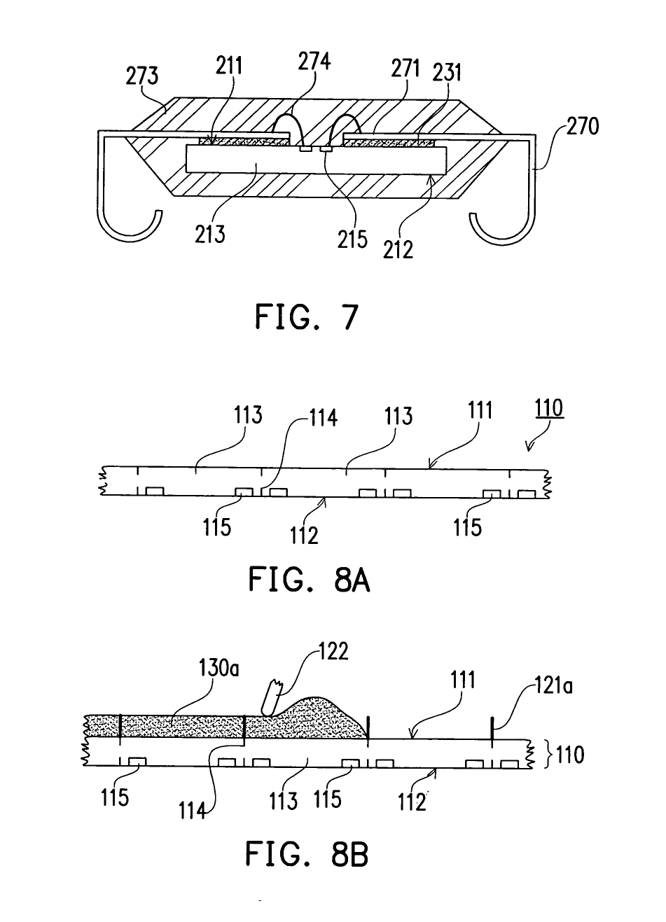

Moreover, in the third embodiment of the present invention, the process steps are the same as those illustrated in the second embodiment shown in FIG. 4A to FIG. 4C. As shown in FIG. 5, the inactive surface 212 of the wafer 210 is directly positioned to a position tape 240. After pre-curing the wafer 210, the active surface 211 of the wafer 210 faces upward and is singulated to form a plurality of chip 213 by the dicer 250. As shown in FIG. 6, the chips 213 with adhesive film 231 are sucked on a carrier 272, then the inner leads 271 of a LOC (Lead-On-Chip) lead frame are attached downward to the active surface 211 of the chip 213. By thermal bonding, the adhesive film 231 becomes adhesive to adhere the chip 213 and the inner leads 271 of lead frame. As shown in FIG. 7, bonding wires 274, molding compound 273 are formed to manufacture a package of TSOP (Thin Small Outline Package) or QFP (Quad Flat Package). Therefore, according to the wafer treating method for making adhesive chips of the present invention, the chips 213 with adhesive film 231 can be massively manufactured at low cost for chip-to-lead frame package.

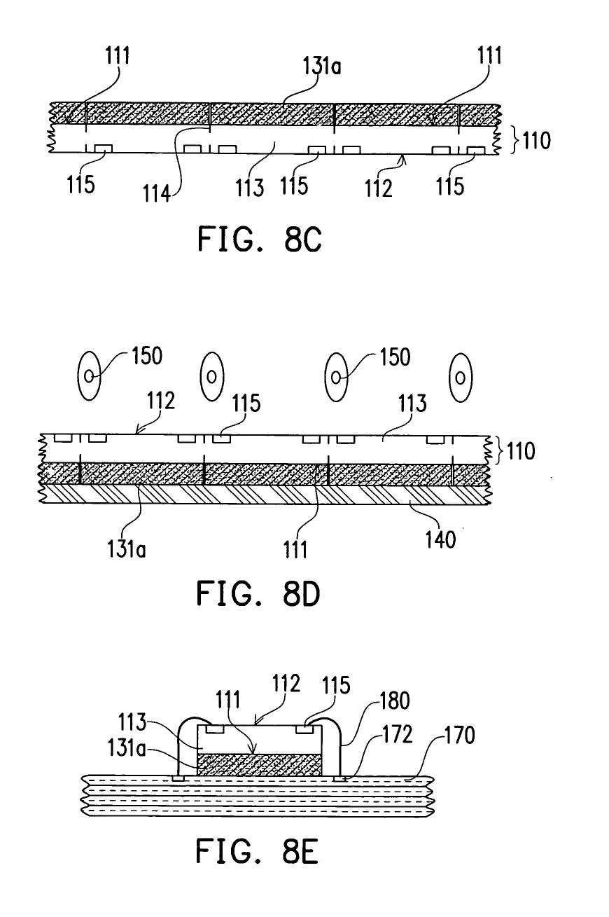

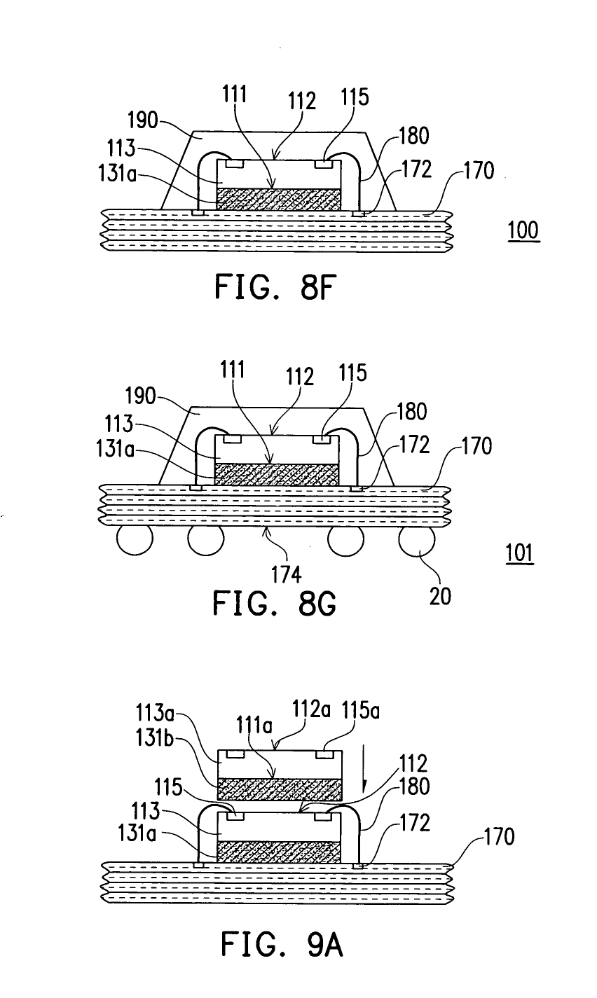

FIG. 8A to FIG. 8D are cross-sectional views of a wafer in wafer treating process in accordance with a fourth embodiment of the present invention. Referring to FIG. 8A, initially a wafer 110 is provided, wherein the wafer 110 has an inactive surface 111, an active surface 112, a plurality of cutting paths 114 and a plurality of bonding pads 115. The bonding pads 115 are disposed on the active surface 112, for example. Referring to FIG. 8B, then a liquid adhesive 130a having at least two-stage property (A-stage, B-stage, C-stage) is coated on total inactive surface 111 of the wafer 110 by such as screen printing, stencil printing or spin coating. Preferably, a screen 121a is placed on the inactive surface 111 of the wafer 110, wherein a plurality of lines of the screen 121a are thinner than that of the screen 121 described in the first embodiment. Then the liquid adhesive 130a with proper flowability is printed on the inactive surface 111 by a scraper 122, wherein the adhesive 130a with two-stage property includes thermosetting resin or polymer such as polyimide, polyquinolin or benzocyclobutene and solvent that enable dissolution of mentioned-above thermosetting resin such as mix-solvent of butyrolactone and cyclopentanone or 1,3,5-mesitylene, etc. It should be noted that the solvent is not required in the adhesive 130a with two-stage property.

Referring to FIG. 8C, next, the wafer 130 is heated at a proper temperature (between about 90 and 150 degree C. approximately) for such as 1 hour and the liquid adhesive 130a is transformed into an adhesive film 131a having B-stage property, wherein the adhesive film 131a with B-stage property has a glass transition temperature (Tg) between −40 and 175 degree C., for example. Referring to FIGS. 8D and 8E, the wafer 110 is cut into a plurality of chips 113 with adhesive film 131a having B-stage property by a positioning tape 140 and a dicer 150, wherein an area of one adhesive film 131a having B-stage property is not larger than an area of the chip 113 thereunder (FIG. 8E shows that the area of the adhesive film 131a having B-stage property is equal to the area of the chip 113). With regard to the adhesive film 131a, the adhesive film 131a can also be an adhesive layer such as an adhesive film, but not limited to the adhesive film having B-stage property.

Compared the figures shown in first embodiment (shown in FIG. 3A to FIG. 3D) with the fourth embodiment in the present invention, the main difference in the fourth embodiment is that a liquid adhesive 130a having at least two-stage property (A-stage, B-stage, C-stage) is coated on an approximate whole inactive surface 111 of the wafer 110. And then, the liquid adhesive 130a is pre-cured by heating or ultraviolet rays, for example, so as to transform the liquid adhesive 130a into an adhesive film 131a with B-stage property. Wherein, the adhesive film 131a can also be an adhesive layer such as an adhesive film, but not limited to the adhesive film having B-stage property. With regard to the remaining elements in the fourth embodiment, their characteristics such as materials or film thickness and their location are the same or similar to that in the first embodiment of the present invention.

FIG. 8E to FIG. 8F are cross-sectional views of an adhesive chip made from the fourth embodiment in chip-to-substrate package. Referring to FIG. 8E, initially a chip 113 with the adhesive film 131a having B-stage property is disposed on a carrier such as a substrate 170 and affixed to the substrate 170 by the adhesive film 131a having B-stage property, wherein an area of the adhesive film 131a is not larger than an area of the chip 113 (FIG. 8E shows that the area of the adhesive film 131a is equal to the area of the chip 113). Then a plurality of bonding pads 115 of the chip 113 are electrically connected with a plurality of bonding pads 172 of the substrate 170 by a plurality of bonding wires 180, for example. Referring to FIG. 8F, thereafter, a molding compound 190 is formed on the substrate 170 to cover the chip 113 and the bonding wires 180, wherein the molding compound 190 can prevent the chip 113 and the bonding wires 180 from damaged by external objects such as dust or moisture, so as to accomplish the manufacture of a chip-to-substrate package structure 100.

FIG. 8G is a cross-sectional view of a chip-to-substrate package structure according to the fourth embodiment in the present invention if applied in a ball grid array package. Referring to FIG. 8G, a plurality of solder balls 20 are disposed on a surface 174 of the substrate 170, so as to accomplish the manufacturing of the ball grid array (BGA) type-chip package 101. Wherein the ball grid array (BGA) type-chip package 101 are electrically connected with such as a printed circuit board (PCB) (not shown) via these solder balls 20.

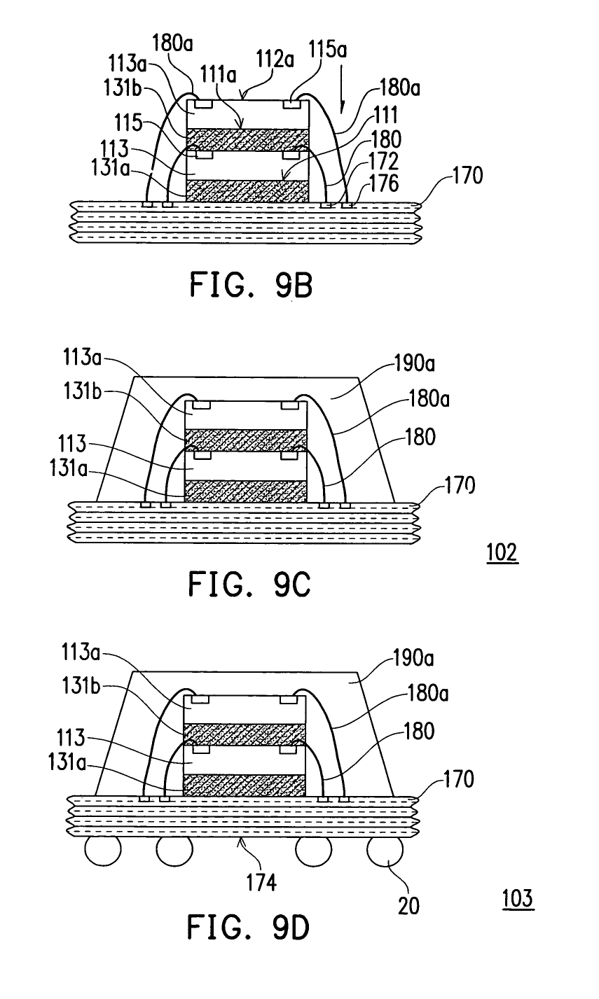

FIG. 9A to FIG. 9C are cross-sectional views of an adhesive chip made from the fourth embodiment in chip-to-chip package. Referring to FIGS. 8E and 9A, following the step shown in FIG. 8E, because the adhesive film 131b having B-stage property does not damage the bonding wires 180 and the bonding pads 115 when covers them, another chip 113a with the adhesive film 131b having B-stage property can be directly disposed on the chip 113 and attached to the chip 113 by the adhesive film 131b having B-stage property, and then the adhesive film 131b having B-stage property is disposed between an inactive 11a of the chip 113a and an active surface 112 of the chip 113. Referring to FIG. 9B, then a plurality of bonding wires 180a can be disposed on a plurality of bonding pads 115a of the chip 113a and a plurality of bonding pads 176 of the substrate 170, so the chip 113a is electrically connected with the substrate 170 via the bonding wires 180a, for example.

Referring to FIG. 9C, thereafter, a molding compound 190a is formed on the substrate 170 to cover the chips 113a and 113 and the bonding wires 180 and 180a to protect them from hurt by external objects such as dust or moisture, so as to complete the manufacturing process of a chip-to-chip package 102. In another embodiment, in the chip-to-chip package 102, the adhesive film 131b can be an adhesive layer such as an adhesive film, which is not limited to the adhesive film having B-stage property, wherein an area of the adhesive film 131b is not larger than an area of the chip 113a (FIG. 9C shows that the area of the adhesive film 131b is equal to the area of the chip 113a). With regard to the adhesive film 131a, the adhesive film 131a also can be an adhesive layer such as an adhesive film, but not limited to the adhesive film having B-stage property.

FIG. 9D is a cross-sectional view of a chip-to-chip package according to the fourth embodiment in the present invention if applied in a ball grid array package. Referring to FIG. 9D, following the step shown in FIG. 9C, a plurality of solder balls 20 can be disposed on a surface 174 of the substrate 170, so as to complete the fabrication of a ball grid array (BGA) type-chip package 103. Wherein the ball grid array (BGA) type-chip package 103 are electrically connected with such as a printed circuit board (PCB) (not shown) via these solder balls 20.

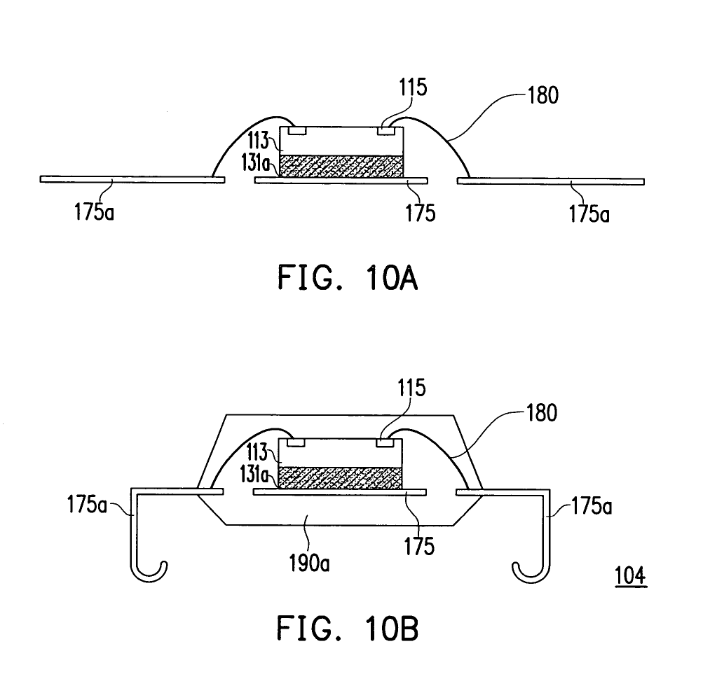

FIG. 10A to FIG. 10B are cross-sectional views of an adhesive chip made from the fourth embodiment in one chip-to-lead frame package. Referring to FIGS. 10A and 8D, following the step shown in FIG. 8D, the chip 113 with the adhesive film 131a having B-stage property can be disposed on a carrier such as a lead frame. The lead frame includes a chip pad 175 and a plurality of leads 175a. The chip 113 with the adhesive film 131a having B-stage property can be disposed and attached to the chip pad 175 by the adhesive film 131a having B-stage property. And then, a plurality of bonding wires 180 can be disposed on a plurality of bonding pads 115 of the chip 113 and the leads 175a, so the chip 113 is electrically connected with the leads 175a by the bonding wires 180, for example.

Referring to FIG. 10B, afterwards a molding compound 190a is formed on the chip pad 175 and the leads 175a to cover the chip 113, the bonding wires 180 and the chip pad 175, so as to complete the manufacturing process of a one chip-to-lead frame package structure 104. And the leads 175a are bent in a shape such as a “J” shape for surface-mount on a printed circuit board (PCB), for example, to be electrically connected with the PCB. Undoubtedly, the number of chips affixed on the lead frame can be more than one, i.e. two, three, four . . . , the following embodiment is taken as a two stacked chips-to-lead frame package, for example.

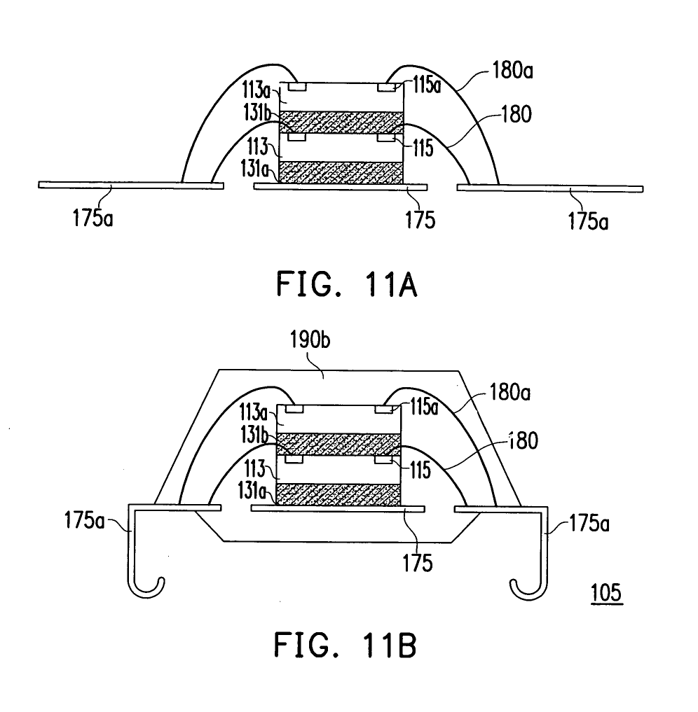

FIG. 11A to FIG. 11B are cross-sectional views of an adhesive chip made from the fourth embodiment in two stacked chips-to-lead frame package. Referring to FIGS. 11A and 10A, following the step shown in FIG. 10A, it should be noted that because the adhesive film 131b having B-stage property does not damage the bonding wires 180 or the bonding pads 115 when covers them, another chip 113a with the adhesive film 131b can be directly disposed on the chip 113 and attached to the chip 113 by the adhesive film 131b having B-stage property. And then, a plurality of bonding wires 180a can be disposed on a plurality of bonding pads 115a of the chip 113a and the leads 175a, so the chip 113a are also electrically connected with the leads 175a by bonding wires 180a, for example.

Referring to FIG. 11B, thereafter a molding compound 190b is formed on the chip pad 175 and the leads 175a to cover the chips 113a and 113, the bonding wires 180 and 180a and the chip pad 175 to protect the chips 113a and 113 from being damaged by external forces such as dust, moisture . . . , etc., so as to accomplish the manufacture of a two stacked chips-to-lead frame package structure 105. And then, the leads 175a are bent in a shape such as a “J” shape for surface-mount on a printed circuit board (PCB), for instance, to be electrically connected with the PCB. It should be noted that in one embodiment of the two stacked chips-to-lead frame package 105, the adhesive film 131b can be an adhesive layer such as an adhesive film, which is not limited to the adhesive film having B-stage property, wherein an area of the adhesive film 131b is not larger than an area of the chip 113a (FIG. 11B shows that the area of the adhesive film 131b is equal to the area of the chip 113a). With regard to the adhesive film 131a, the adhesive film 131a can also be an adhesive layer such as an adhesive film, but not limited to the adhesive film having B-stage property.

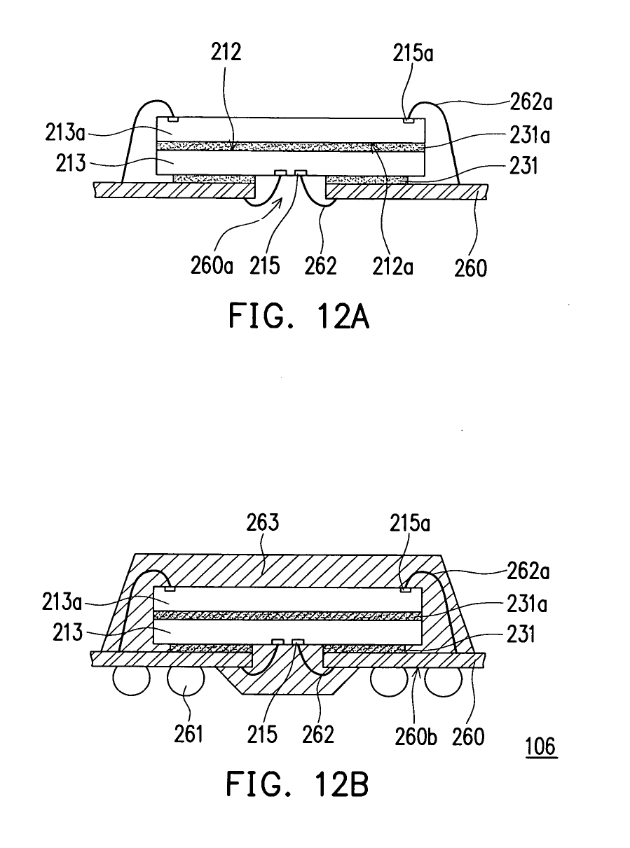

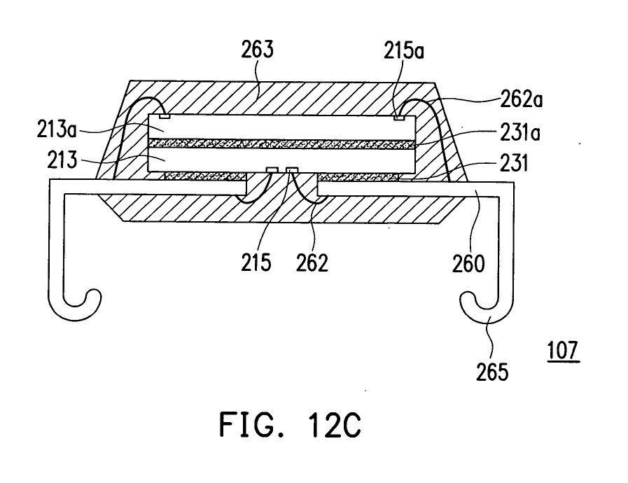

FIG. 12A is a cross-sectional view of an adhesive chip made from the fifth embodiment in chip-to-chip package. Referring to FIGS. 4E and 12A, in fifth embodiment, after the chip 213 with the adhesive film 231 having B-stage property is affixed to the carrier 260, another chip 213a with another adhesive film 231a having B-stage property can be affixed to the chip 213, i.e. the adhesive film 231a having B-stage property is disposed between the inactive surface 212 of the chip 213 and an inactive surface 212a of the chip 213a, wherein the chip 213a with another adhesive film 231a having B-stage property can be made by the manufacturing process described in the fourth embodiment of the present invention shown in FIGS. 8A to 8D. With regard to the remaining elements in the fifth embodiment, their characteristics such as materials or film thickness and their disposed location are the same or similar to that described in the second embodiment of the present invention.

With reference to FIG. 12A, in another embodiment, the adhesive film 231a can be an adhesive layer such as an adhesive film, which is not limited to the adhesive film having B-stage property. And an area of the adhesive film 231a is not larger than an area of the chip 213a (FIG. 12A shows that the area of the adhesive film 231a is equal to the area of the chip 213a). In addition, the adhesive film 231 also can be an adhesive layer such as an adhesive film, which is not limited to the adhesive film having B-stage property. Moreover, an area of the adhesive film 231 is not larger than an area of the chip 213 (FIG. 12A shows that the area of the adhesive film 231 is smaller than the area of the chip 213).

FIG. 12B is a cross-sectional view of a chip-to-chip package according to the fifth embodiment in the present invention if applied in a ball grid array package. The carrier 260 can be not only a substrate but also a lead-frame. Referring to FIGS. 12A and 12B, if the carrier 260 is a substrate such as a tape substrate or a ceramic substrate, which is utilized for such as a ball grid array package, then a plurality of solder balls 261 can be disposed on a surface 260b of the carrier 260 and a molding compound 263 is formed on the carrier 260 to cover the chips 213a and 213 and the bonding wires 262 and 262a, so as to accomplish the manufacturing of the ball grid array (BGA) type-chip package 106.

FIG. 12C is a cross-sectional views of an adhesive chip made from the fifth embodiment in two stacked chips-to-lead frame package. Referring to FIGS. 12A and 12C, if the carrier 260 is a lead-frame, after the chip 213a with the adhesive film 231a having B-stage property is disposed on the chip 213, a molding compound 263 is formed on the carrier 260 to cover the chips 213a and 213 and the bonding wires 262 and 262a. Then the manufacture of a two stacked chips-to-lead frame package structure 107 is accomplished, wherein the leads 265 are bent in a shape such as a “J” shape for surface-mount on a printed circuit board (PCB), for instance, to be electrically connected with the PCB.

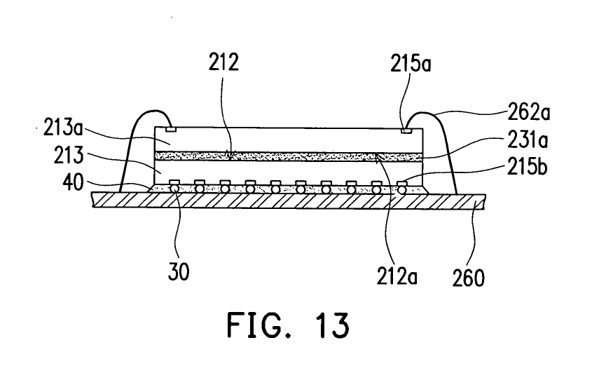

FIG. 13 is a cross-sectional view of FIG. 12A if the first chip is electrically connected with the carrier via a plurality of solder bumps. Referring to FIGS. 12A and 13, besides the bonding wires 262, the electrical connection between the carrier 260 and the chip 213 can be achieved by a plurality of solder bumps 30 (i.e. the Flip Chip type connection), wherein the solder bumps 30 can be disposed on a plurality of solder pads 215a. So in the embodiment, the carrier 260 does not have a through hole (not shown) to pass the bonding wires 262 therethrough. And an underfill 40, for example, can be disposed between the carrier 260 and the chip 213 to cover the solder bumps 30, so as to reduce the stresses among the carrier 260, the chip 213 and the solder bumps 30, then the possibility of the broken solder bumps 30 is lowered.

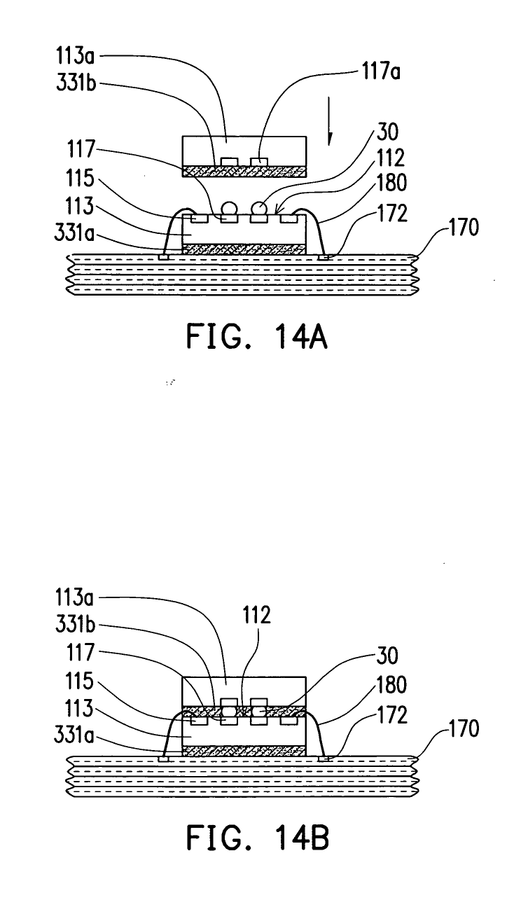

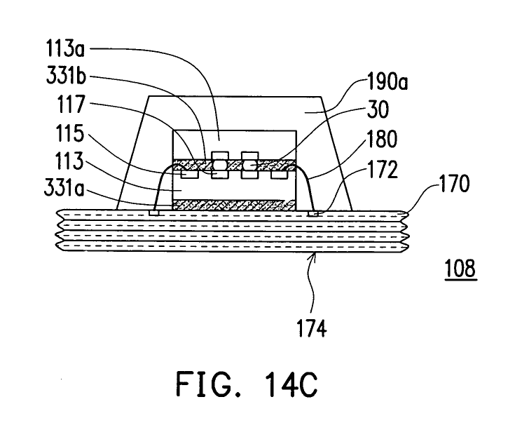

FIG. 14A to FIG. 14C are cross-sectional views of an adhesive chip made from a sixth embodiment in chip-to-chip package. Referring to FIG. 14A, compared with the step shown in FIG. 9A, the adhesive films 331a or 331b having B-stage property are thinner than the adhesive film 131a or 131b having B-stage property. Additionally, the adhesive films 331b having B-stage property is disposed between an active surface of the chip 113a and an active surface 112 of the chip 113. The chip 113 has a plurality of bonding pads 115 and a plurality of solder pads 117 on its active surface 112, wherein a plurality of solder bumps 30 are disposed on the solder pads 117. Referring to FIG. 14B, because the adhesive film 331b having B-stage property does not damage the bonding wires 180, the solder bumps 30 and the bonding pads 115 when covers them, another chip 113a with the adhesive film 331b having B-stage property can be directly disposed on the chip 113 and attached to the chip 113 by the adhesive film 331b having B-stage property, wherein the chips 113 and 113a are electrically connected via the solder bumps 30, for example. It should be noted that the location of the solder pads 117 can be changed by implementing a redistribution layer (RDL) technique on the active surface 112 of the chip 113, for example.

Referring to FIG. 14C, thereafter, a molding compound 190a is formed on the substrate 170 to cover the chips 113a and 113 and the bonding wires 180 to protect them from hurt by external objects such as dust or moisture, so as to complete the manufacturing process of a chip-to-chip package 108. In another embodiment, in the chip-to-chip package 108, the adhesive film 331b can be an adhesive layer such as an adhesive film, which is not limited to the adhesive film having B-stage property, wherein an area of the adhesive film 331b is not larger than an area of the chip 113a (FIG. 14C shows that the area of the adhesive film 331b is equal to the area of the chip 113a). With regard to the adhesive film 331a, the adhesive film 331a also can be an adhesive layer such as an adhesive film, but not limited to the adhesive film having B-stage property. In addition, similar to the step shown in FIG. 9D, a plurality of solder balls (not shown) can be disposed on the surface 174 of the substrate 170 to complete the fabrication of a ball grid array (BGA) type-chip package.

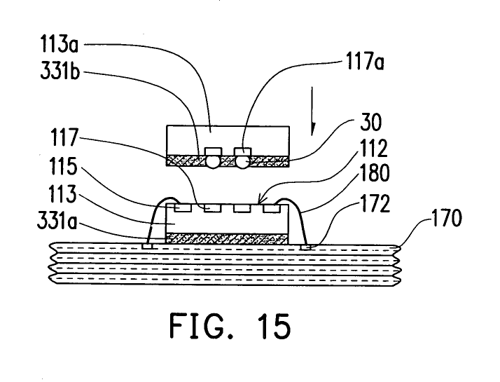

FIG. 15 is another embodiment for disposing solder bumps 30 shown in FIG. 14A. Referring to FIGS. 14A and 15, the chip 113a has a plurality of solder pads 117a on its active surface. Compared to the disposition of the solder bumps 30 shown in FIG. 14A, the solder bumps 30 can be disposed on the solder pads 117a and be covered with the adhesive films 331b having B-stage property. Then the steps shown in FIGS. 14B and 14C can be implemented, so as to complete the fabrication of a ball grid array (BGA) type-chip package.

It should be noted that the chip-to-chip staked structures shown in FIGS. 9C, 11A, 12A, 13, 14C and 15 are not limited to two chips staked structure, they can further include more than two chips, i.e. three, four . . . , chips staked structures in the present invention if the manufacturing process thereof is feasible. Additionally, in all embodiments of the present invention, the adhesive films having B-stage property can be an adhesive layer such as an adhesive film. In addition, in the present invention, the electrical connection between the carrier and the chip is not limited to the Wire Bonding type connection; it also comprises the Flip Chip type connection.

In summary, the present invention, a wafer treating method for making adhesive chips and a chip package, utilizing the adhesive film with B-stage property has the following advantages.

(1). Compared to the conventional method by using a liquid thermosetting adhesive which contaminates the bonding pads of the lowered chip easily, the adhesive film having B-stage property utilized in the present invention will not hurt the bonding wires or bonding pads of existed chip-to-substrate or chip-to-lead frame package structure. Therefore, the chip with the adhesive film having B-stage property can be easily stacked on the existed chip-to-substrate, or chip-to-lead frame package structure even when the wafer-level thermal-bonding adhesive film having B-stage property fully covers an inactive surface of a chip without taking account into the influence of an adhesive layer on the bonding wires or bonding pads.

(2). Compared to the conventional method for making adhesive chips or chip package by using a solid polyimide tape with high cost, the present invention utilizing the adhesive film having B-stage property will fabricate the chip-to-chip stack, chip-to-substrate, or chip-to-lead frame package structure at low cost.

The above description provides a full and complete description of the embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A wafer treating method for making adhesive chips comprising the steps of:
providing a wafer having a surface;
coating a liquid adhesive with two-stage property on the surface of the wafer;
pre-curing the liquid adhesive by heating or ultraviolet rays so that the liquid adhesive transforms into an adhesive film having B-stage property;
providing a positioning tape in contact with the adhesive film for positioning the wafer; and
singulating the wafer on the positioning tape so as to form a plurality of chips with the adhesive film.

2. A chip package, comprising:
a carrier;
a first chip, disposed on the carrier and electrically connected with the carrier;
a first adhesive layer, disposed between the carrier and the first chip, wherein an area of the first adhesive layer is not larger than an area of the first chip; and
a molding compound, disposed on the carrier to cover the first chip.

3. The chip package in accordance with claim 2, further comprising a plurality of first bonding wires, electrically connected with the carrier and the first chip.

4. The chip package in accordance with claim 2, wherein the carrier is a package substrate or a lead frame.

5. The chip package in accordance with claim 4, wherein the package substrate has a slit exposing a portion of the first chip.

6. The chip package in accordance with claim 2, wherein the first adhesive layer is an adhesive film.

7. The chip package in accordance with claim 6, wherein the first adhesive layer is an adhesive film having B-stage property.

8. The chip package in accordance with claim 2, further comprising:
a second adhesive layer, disposed on the first chip; and
a second chip, disposed on the second adhesive layer, wherein an area of the second adhesive layer is not larger than a area of the second chip, and wherein the second chip is electrically connected with the carrier.

9. The chip package in accordance with claim 8, further comprising a plurality of second bonding wires, electrically connected with the carrier and the second chip.

10. The chip package in accordance with claim 9, wherein a portion of the first bonding wires are covered with the second adhesive layer.

11. The chip package in accordance with claim 9, wherein the second bonding wires and the second chip are covered with the molding compound.

12. The chip package in accordance with claim 8, wherein the second adhesive layer is disposed between an inactive surface of the second chip and an inactive surface of the first chip.

13. The chip package in accordance with claim 8, wherein the second adhesive layer is disposed between an inactive surface of the second chip and an active surface of the first chip.

14. The chip package in accordance with claim 8, wherein the second adhesive layer is disposed between an active surface of the second chip and an active surface of the first chip.

15. The chip package in accordance with claim 8, wherein the second adhesive layer is an adhesive film.

16. The chip package in accordance with claim 15, wherein the second adhesive layer is an adhesive film having B-stage property.

17. A chip package, comprising:
a carrier;
a first chip, disposed on the carrier and electrically connected with the carrier;
a second chip, disposed on the first chip and electrically connected with the carrier;
a second adhesive layer, disposed between the first chip and the second chip, wherein an area of the second adhesive layer is not larger than an area of the second chip; and
a molding compound, disposed on the carrier to cover the first chip, the second chip, and the second adhesive layer.

18. The chip package in accordance with claim 17, furthering comprising a plurality of first bonding wires, electrically connected with the carrier and the first chip.

19. The chip package in accordance with claim 18, wherein a portion of the first bonding wires are covered with the second adhesive layer.

20. The chip package in accordance with claim 17, further comprising a plurality of second bonding wires, electrically connected with the carrier and the second chip.

21. The chip package in accordance with claim 17, wherein the second adhesive layer is an adhesive film.

22. The chip package in accordance with claim 21, wherein the second adhesive layer is an adhesive film having B-stage property.

23. The chip package in accordance with claim 17, further comprising a first adhesive layer, disposed between the carrier and the first chip.

24. The chip package in accordance with claim 23, wherein the first adhesive layer is an adhesive film.

25. The chip package in accordance with claim 24, wherein the first adhesive layer is an adhesive film having B-stage property.

26. The chip package in accordance with claim 17, wherein the carrier is a package substrate or a lead frame.

27. The chip package in accordance with claim 26, wherein the carrier has a slit exposing a portion of the first chip.

28. The chip package in accordance with claim 17, wherein the second adhesive layer is disposed between an inactive surface of the second chip and an inactive surface of the first chip.

29. The chip package in accordance with claim 28, wherein the first chip is electrically connected with the carrier via a plurality of solder bumps.

30. The chip package in accordance with claim 17, wherein the second adhesive layer is disposed between an inactive surface of the second chip and an active surface of the first chip.

31. The chip package in accordance with claim 17, wherein the second adhesive layer is disposed between an active surface of the second chip and an active surface of the first chip.
